(19) United States
(12) Patent Application Publication
(10) Pub. No.: US 2015/0094975 A1
(43) Pub. Date: Apr. 2, 2015

(54) WAVELET TRANSFORM SYSTEM AND METHOD FOR VOLTAGE EVENTS DETECTION AND CLASSIFICATION

(71) Applicant: KING FAHD UNIVERSITY OF PETROLEUM AND MINERALS, Dhahran (SA)

(72) Inventors: FOUAD RASHED FOUAD ZARO, DHAHRAN (SA); MOHAMMAD ALI ABIDO, DHAHRAN (SA); MOHAMED A. EL-GEBEILY, DHAHRAN (SA)

(73) Assignee: KING FAHD UNIVERSITY OF PETROLEUM AND MINERALS, Dhahran (SA)

(21) Appl. No.: 14/043,766

(22) Filed: Oct. 1, 2013

(51) Int. Cl. G01R 25/00; G01R 19/00

(52) U.S. Cl. CPC G01R 25/00; G01R 19/0084
USPC 702/66

(57) ABSTRACT

Wavelet transform systems and methods for voltage events detection and classification are provided and include a wavelet multiresolution analysis-based real time detection and classification for voltage events, as developed on a LabVIEW® platform. In the wavelet transform systems and methods for voltage events detection and classification, a finest detail level is utilized to detect the start time, the end time, and the duration of the voltage events, whereas a coarsest approximation level is used to classify the voltage event types. The wavelet transform systems and methods for voltage events detection and classification are applied on several typical short duration voltage events, such as sag, swell, and interruption.

### BACKGROUND OF THE INVENTION

1. Field of the Invention

The present invention relates to power quality (PQ) measurements, and particularly to a wavelet transform systems and methods for voltage events detection and classification.

2. Description of the Related Art

Modern electric power systems with new distributed renewable power sources such as wind power and solar power have seen the participation of a large amount of new power electronic devices. The recently developed technology related to the concept of “smart grid” in power systems also contributes to make the system more complex. The increasing use of power electronics devices contributes further to the arising power quality (PQ) problem. That is becoming a serious problem, and has been a great threat to the safety of electric power systems and the national economy as a whole. Hence, for better understanding the PQ problems, a comprehensive monitoring system that integrates the effective measurement, control, communication and supervision of PQ must be developed. That can serve as a vital diagnostic tool and help to identify the cause of PQ disturbances and even possible to identify problem conditions before they cause disturbances. The international organizations working on PQ issues include IEEE and IEC recommend guidelines for PQ monitoring.

Along with technology advances, many companies worldwide applied minimization/elimination measures for PQ problems to increase their productivity. The most affected areas by PQ problems are the continuous process industry and the information technology services. When a disturbance occurs, huge financial losses may happen, with the consequent loss of productivity and competitiveness. Also, the automated classification of PQ disturbances can be a significant issue for real-time PQ monitoring especially in the deregulated era.

The continuous wavelet transform (CWT) and Fourier transform (FT) have been proposed to detect and analyze PQ disturbances. However, CWT and FT have some limitations for on-line PQ monitoring applications. CWT is a redundant transformation where the excessive amount of information may affect the identification and classification process. On the other hand, since FT has fixed frequency resolution, it is not suitable for characterization of voltage transient phenomena that needs flexible frequency resolution. Also, artificial intelligence and machine learning are presented for classification of PQ disturbances as powerful tools. Recent advances in discrete wavelet transforms (DWT) can provide a powerful tool for PQ disturbances detection, localization, and classification. The dyadic-orthonormal wavelet transform was utilized to detect and localize various types of PQ disturbances where the squared wavelet transform coefficients at each scale are used to find a unique feature. Such a feature can be used to classify different PQ disturbances using a proper classification tool. The wavelet multiresolution signal decomposition was proposed for analyzing the PQ transient events. Generally speaking, some features have been proposed in literature to classify different PQ problems. These include: (a) the standard deviation curve at different resolution levels; (b) the delta standard deviation multiresolution analysis at each decomposition level; (c) the energy distribution of the wavelet part at each decomposition level; (d) the inductive inference approach; and (e) the obtained wavelet coefficients at each decomposition level. It is worth mentioning that the reported approaches utilize all the wavelet decomposition levels to extract the feature that can be used to classify PQ disturbances. There remains a need, however, to utilize less information in order to make the decomposition more suitable for on-line applications.

Thus, a wavelet transform system and method for voltage events detection and classification addressing the aforementioned problems is desired.

### SUMMARY OF THE INVENTION

Wavelet transform systems and methods for voltage events detection and classification provide a wavelet multiresolution analysis-based real time detection and classification technique for voltage events, such as developed on LabVIEW® platform. In the wavelet transform systems and methods for voltage events detection and classification, the finest, or first, detail level is utilized to detect the start time, the end time, and the duration of the voltage events, whereas the coarsest, or last, approximation level is used to classify the voltage event types. Wavelet transform systems and methods for voltage events detection and classification can be applied on several typical short duration voltage events, such as sag, swell, and interruption.

These and other features of the present invention will become readily apparent upon further review of the following specification and drawings.

### BRIEF DESCRIPTION OF THE DRAWINGS

FIG. 1 is a flowchart of the wavelet transform method according to the present invention.

FIGS. 2A-2D depict a virtual instrument block diagram (system 200 including components 200a-200d) of an embodiment of a voltage monitoring system as can be implemented in embodiments of wavelet transform systems and methods for voltage events detection and classification according to the present invention.

FIG. 3A show oscillographic approximation level plots of the first six decomposition levels of the test signals.

FIG. 3B show oscillographic detail level plots of the first six decomposition levels of the test signals.

FIG. 4A shows a plot of the voltage interruption details of the interruption test signals.

FIG. 4B shows a plot of the voltage interruption waveform of the interruption test signals.

FIG. 4C shows a plot of the first detail MRA level of the interruption test signals

FIG. 4D shows a plot of the voltage interruption waveform within the disturbance period.

FIG. 4E shows a plot of the nominal voltage waveform within the disturbance period.

FIG. 4F shows a plot of the coarsest approximation MRA level for plot 400d.

FIG. 4G shows a plot of the coarsest approximation MRA level for plot 400e.

FIG. 5A shows the sag voltage event details.

FIG. 5B shows a plot of the voltage sag waveform.

FIG. 5C shows a plot of the first detail MRA level for plot 500b.

FIG. 5D shows a plot of the voltage sag waveform within the disturbance period.

FIG. 5E shows a plot of the nominal voltage within the disturbance period.

FIG. 5F shows a plot of the coarsest approximation MRA level for plot 500d.

FIG. 5G shows a plot of the coarsest approximation MRA level for plot 500e.

FIG. 6A shows the voltage event details for swell type disturbance.

FIG. 6B shows a plot of the voltage swell waveform.

FIG. 6C shows a plot of the first detail MRA level for plot 500b.

FIG. 6D shows a plot of the voltage swell waveform within the disturbance period.

FIG. 6E shows a plot of the nominal voltage waveform within the disturbance period.

FIG. 6F shows a plot of the coarsest approximation MRA level for 500d.

FIG. 6G shows a plot of the coarsest approximation MRA level for 500e.

FIG. 7 illustrates a generalized processing system for implementing embodiments of wavelet transform systems and methods for voltage events detection and classification according to the present invention.

FIG. 8 illustrates a voltage monitoring system to implement embodiments of the wavelet transform systems and methods for voltage events detection and classification according to the present invention.

Similar reference characters denote corresponding features consistently throughout the attached drawings.

### DETAILED DESCRIPTION OF THE PREFERRED EMBODIMENTS

At the outset, it should be understood by one of ordinary skill in the art that embodiments of wavelet transform systems and methods for voltage events detection and classification can include software or firmware code executing on a computer, a microcontroller, a microprocessor, or a DSP processor; state machines implemented in application specific or programmable logic; or numerous other forms without departing from the spirit and scope of the method described herein. Embodiments of wavelet transform system and methods for voltage events detection and classification can be provided and implemented as a computer program, which includes a non-transitory machine-readable medium having stored thereon instructions that can be used to program a computer (or other electronic devices) to perform a process according to the method. The machine-readable medium can include, but is not limited to, floppy diskettes, optical disks, CD-ROMs, and magneto-optical disks, ROMs, RAMs, EPROMs, EEPROMs, magnetic or optical cards, flash memory, or other type of media or machine-readable medium suitable for storing electronic instructions.

Embodiments of wavelet transform systems and methods for voltage events detection and classification provide a wavelet multiresolution analysis-based real time detection and classification technique for voltage events, such as developed on a LabVIEW® platform. In embodiments of wavelet transform systems and methods for voltage events detection and classification the finest detail level is utilized to detect the start time, the end time, and the duration of the voltage events, whereas the coarsest approximation level is used to classify the voltage event types. Embodiments of wavelet transform systems and methods for voltage events detection and classification can be applied on several typical short duration voltage events such as sag, swell, and interruption. Embodiments of wavelet transform systems and methods for voltage events detection and classification use a plurality of decomposition levels, such as two decomposition levels, of wavelet multi-resolution analysis (MRA) to detect and classify voltage events. Embodiments of wavelet transform systems and methods for voltage events detection and classification can use the finest decomposition level of MRA to detect the characterization of voltage events and can use the coarsest decomposition level of MRA to classify the voltage events. Moreover, embodiments of wavelet transform systems and methods for voltage events detection and classification can reduce the processing time of the voltage signals analysis.

Wavelet multiresolution analysis (MRA) is an attractive technique for analyzing PQ waveforms, particularly for studying disturbance or transient waveforms where it is necessary to examine different frequency components separately. This is because of its ability in segregating a signal into multiple frequency bands with optimized resolutions. MRA is capable of revealing aspects of data that other analysis tools can miss, such as trends, discontinuities, breakdown points, and self-similarity. Also, MRA has proven to be a relatively strong and efficient in feature extraction from PQ disturbance data, for example.

The distorted signal can be decomposed using MRA into different resolution levels. Generally, any changes in the smoothness of the signal can be detected and localized at the finer resolution levels. The first finer decomposition levels are adequate to detect and localize the disturbance. However, the coarser resolution levels are used to extract more features that can help in the classification process.

The distribution of energy across the multiple frequency bands forms patterns that have been found to be useful for classifying between different PQ disturbances. If the used wavelet and scaling functions form an orthonormal set of basis, then the Parseval's theorem relates the energy of the distorted signal to the values of the coefficients. This means that the energy or norm of the signal can be partitioned according to the following:

$$\int {\vert f ( t ) \vert}^{2} d t = {\sum }_{k} {\vert {A}_{j 0} ( k ) \vert}^{2} + {\sum }_{j \leq {j}_{0}} {\sum }_{k} {\vert {D}_{j} ( k ) \vert}^{2} , \qquad ( 1 )$$

where Aⱼ₀ represents the coarsest approximation level that contains the fundamental frequency, Dⱼ represents the detail level of the j^{th} decomposition level, and k represents the wavelet coefficients at each decomposition level.

Short-duration voltage events are typically in eruption, sag and swell. Such events are likely caused by fault conditions, energization of large loads that require high starting currents, or intermittent loose connections in power wiring. Voltage interruption typically occurs when the supply voltage decreases to less than 10% of nominal root mean square (rms) voltage (V) for a time period not exceeding 1.0 minute (min). Voltage interruptions are usually associated with power system faults, equipment failures, and control malfunctions. Voltage sag is a decrease in rms voltage to the range between 10% and 90% of a nominal rms voltage for durations from 0.5 cycles to 1.0 min, for example. Voltage sags can be a result of system faults, switching heavy loads, starting large motors or large load changes. A voltage swell is the converse to the sag where there is an increase in rms voltage above 110% to 180% of a nominal voltage for durations of 0.5 cycles to 1.0 min, for example. Voltage swells are usually associated with system faults, switching on capacitor banks and incorrect settings of off-tap changers in power substations, for example.

Although rms methods are relatively simple in voltage event detection, the rms methods can suffer from the dependency on the window length and a time interval for updating the values. In this regard, depending on the selection of these two parameters, the magnitude and the duration of a voltage event can be inaccurate. However, in contrast, use of a MRA can produce more accurate results that can be useful for determining the causes of such events. Embodiments of wavelet transform systems and methods for voltage events detection and classification utilize MRA with relatively less information than rms methods and, thus, are relatively more suitable for on-line implementation.

Generally, a signal f can be decomposed into approximation and details components, as follows:

$$f = {\sum }_{k} {a}_{{j}_{0} k} {ϕ}_{{j}_{0} k} + {\sum }_{j \leq {j}_{0}} {\sum }_{k} {d}_{jk} {ψ}_{jk} , \qquad ( 2 )$$

where,

ψⱼₖ(t)=2^{-j/2}ψ(2^{-j}t−k), (3)

φⱼ_{₀}ₖ(t)=2^{-j}^{₀}^{/2}φ(2^{-j}^{₀}t−k), (4)

ψ(t) and φ(t) represent the mother wavelet and the scaling function respectively, and

dⱼₖ=∫f(t)ψⱼₖ(t)dt, and (5)

αⱼ_{₀}ₖ=∫f(t)φvⱼ_{₀}ₖ(t)dt. (6)

It can be observed that coefficients corresponding to orthogonal signals are typically orthogonal sequences. Therefore, where f, \tilde{f} are orthogonal signals, i.e.,

[symbol]

f, \tilde{f} [symbol] =0, and (∫f(t)\tilde{f}(t) dt=0), (7)

where,

$$f = {\sum }_{j , k} {d}_{jk} {ψ}_{jk} , and \tilde{f} = {\sum }_{{j}^{′} , {k}^{′}} {\tilde{d}}_{{j}^{′} {k}^{′}} {ψ}_{{jk}^{′}} . \qquad ( 8 )$$

These relations yield:

$$\begin{matrix}0 = 〈 f , \tilde{f} 〉 = 〈 {\sum }_{j , k} {d}_{jk} {ψ}_{jk} , {\sum }_{{j}^{′} , {k}^{′}} {\tilde{d}}_{{j}^{′} {k}^{′}} {ψ}_{{jk}^{′}} 〉 & \\ = {\sum }_{j , k} {\sum }_{{j}^{′} , {k}^{′}} {d}_{jk} {\tilde{d}}_{{j}^{′} {k}^{′}} 〈 {ψ}_{jk} , {ψ}_{{jk}^{′}} 〉 , & ( 10 )\end{matrix} \qquad ( 9 )$$

since,

[symbol]

ψⱼₖ, ψ_{jk′} [symbol] =δ_{jkj′k′.} (11)

### Therefore,

$$0 = {\sum }_{jk} {d}_{jk} {\tilde{d}}_{{j}^{′} {k}^{′}} . \qquad ( 12 )$$

According to (12), (dⱼₖ) and (\tilde{d}_{j′k′}) are orthogonal sequences.

Therefore the pure sinusoidal signal is orthogonal to high frequency disturbances. The same argument is true about the wavelet coefficients. Thus, taking an inner product of a pure signal (f) with one that has high frequency disturbance (g+h) can eliminate the effect of the high frequency disturbance (h). Therefore,

[symbol]

f, g+h [symbol] =(f, g)+(f, h)=(f, g). (13)

The voltage sag, swell, and interruption are scaled versions of the original pure signal over the disturbance period (I_{d}). Therefore, they should correlate well over I_{d} with the pure signal at the coarsest approximation level. The following notations shown in Table 1 have been used.

TABLE 1
Summary of notations used

| Notation | Definition |
|---|---|
| f | Pure signal. |
| (dⱼₖ)_{k∈z} | Wavelet detail |
| | coefficients of the pure |
| | signal at the scale level j. |
| s | Disturbance signal which |
| | is zero outside I_{d}, that is |
| | s(t) = 0 for t ∉ I_{d}. |
| | I_{d} will be called the |
| | support of s. |
| (\tilde{d}ⱼₖ)_{k∈Δj} | Wavelet coefficients of |
| | the disturbance signal at |
| | the coarsest |
| | approximation level j₀ |
| | over the disturbance |
| | interval I_{d}, where, as in |
| | (14), |
| | Δⱼ = {k: supp ψⱼₖ ⊂̅ I_{d}} |

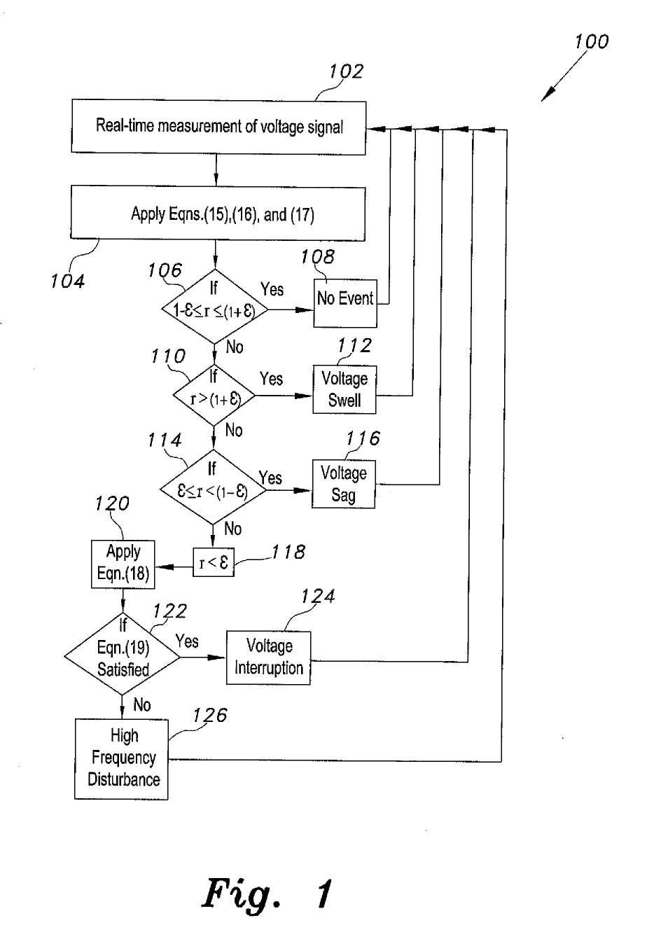

FIG. 1 shows the flow chart of an embodiment of a disturbance discrimination algorithm in implementing embodiments of a wavelet transform system and method for voltage events detection and classification. The wavelet transform method for voltage events detection and classification employs Daubechies 6 (db6) as the mother wavelet to detect and classify all the transient disturbances in the distorted signal, since, as known by artisans having ordinary skill, it is typically the most appropriate mother wavelet used to detect the voltage events.

The following procedure shown in Table 2 is used to discriminate between the three types of considered disturbances, such as in relation to voltage swell, voltage sag and voltage interruption, for example. In this regard, a disturbance discrimination process or procedure 100, based upon the relations of Table 2, is illustrated in FIG. 1, as can be implemented in embodiments of a wavelet transform system and method for voltage events detection and classification. In the disturbance discrimination process or procedure in FIG. 1, a first step 102 includes taking a real time measurement of the voltage signal. Step 104 then applies the equations (15) through (17). Step 106 compares the ratio calculated in equation 17, r, in an inequality test pair to determine whether an anomalous event, such as at least one of a no fault event, a swell fault event, a sag fault event or an interruption fault event, has occurred. If no anomalous event has occurred, step 108 declares no event and causes processing to loop back to step 102 and take another voltage signal measurement. Step 110 compares the ratio r in a second inequality test. If the step 110 condition is true, a voltage swell is declared at step 112 before looping back to step 102. Step 114 compares the ratio r in a third inequality test. If the step 114 condition is true, a voltage sag is declared at step 116 before looping back to step 102. Step 118 compares the ratio r in a fourth inequality test and passes the results to step 120 which applies equation (18). At step 122 a test is performed to determine if equation (19) is satisfied after the application at step 120. If equation (19) was satisfied, then step 124 declares voltage interruption before looping back to step 102. If equation (19) was not satisfied, then step 126 declares a high frequency disturbance before looping back to step 102.

In the above disturbance discrimination process or procedure 100, a first result

$${‖ ( {d}_{{j}_{0} k} ) ‖}_{{Δ}_{{j}_{0}}}$$

of a finest detail level of a pure signal based on wavelet coefficients [symbol] of the pure signal is computed, a second result

$${‖ ( {\tilde{d}}_{{j}_{0} k} ) ‖}_{{Δ}_{{j}_{0}}}$$

of a coarsest level of a disturbance signal based upon wavelet coefficients (\tilde{d}ⱼₖ)_{k ε {}_{ⱼ} of the disturbance signal is computed, and a third result r relating the second result of the coarsest level to the first result of the finest detail level is computed. From Table 1 and as applied to the relations in Table 2, (dⱼₖ) and (\tilde{d}_{j′k′}) are orthogonal sequences, (\tilde{d}ⱼₖ)_{k ε Δ}_{ⱼ} are wavelet coefficients of the disturbance signal at the coarsest approximation level j₀ over the disturbance interval I_{d}, where Δⱼ={k: supp ψⱼₖ⊂I_{d}}, k corresponds to the wavelet coefficients at a level, supp ψⱼₖ corresponds to a mother wavelet, and [symbol] are wavelet coefficients of the pure signal at the scale level j and [symbol] is a level group, and Fⱼ corresponds to a result in the interruption fault event type determination.

TABLE 2
Disturbance Discrimination Algorithm

| Step# | Action | |
|---|---|---|
| 1 | Compute, | |
| | ${\vert \vert ( {d}_{{j}_{0} k} ) \vert \vert}_{{Δ}_{{j}_{0}}} = {( {\sum }_{k ∈ {Δ}_{{j}_{0}}} {d}_{{j}_{0} k}^{2} )}^{\frac{1}{2}}$ | (15) |
| | ${\vert \vert ( {\tilde{d}}_{{j}_{0} k} ) \vert \vert}_{{Δ}_{{j}_{0}}} = {( {\sum }_{k ∈ {Δ}_{{j}_{0}}} {\tilde{d}}_{{j}_{0} k}^{2} )}^{\frac{1}{2}}$ | (16) |
| | $and r = \frac{{\vert \vert ( {\tilde{d}}_{{j}_{0} k} ) \vert \vert}_{{Δ}_{{j}_{0}}}}{{\vert \vert ( {d}_{{j}_{0} k} ) \vert \vert}_{{Δ}_{{j}_{0}}}}$ | (17) |
| 2 | If (1 − ε) ≦ r ≦ | |
| | (1+ ε), then there is no | |
| | event, (ε is a preassigned | |
| | theshold; assumed in | |
| | this work ε = 0.1). | |
| 3 | If r > (1 + ε), the | |
| | disturbance corresponds | |
| | to a swell | |
| 4 | if ε ≦ r < (1 − ε), the | |
| | disturbance corresponds | |
| | to a sag. | |
| 5 | if r < ε, then: | |
| | (a). Compute Fⱼas: | |
| | ${F}_{j} = {\sum }_{k ∈ {Δ}_{j}} {d}_{jk} {\tilde{d}}_{jk} ,$ | (18 |
| | j = 1, . . . , j₀ − 1 | |
| | and (b). Check the following condition: | |
| | ${\sum }_{j = 1}^{j} {f}_{j}^{2} \leq {ɛ}^{2} .$ | (19) |

If satisfied, then the disturbance corresponds to an interruption. Otherwise, it corresponds to some other high frequency disturbance.

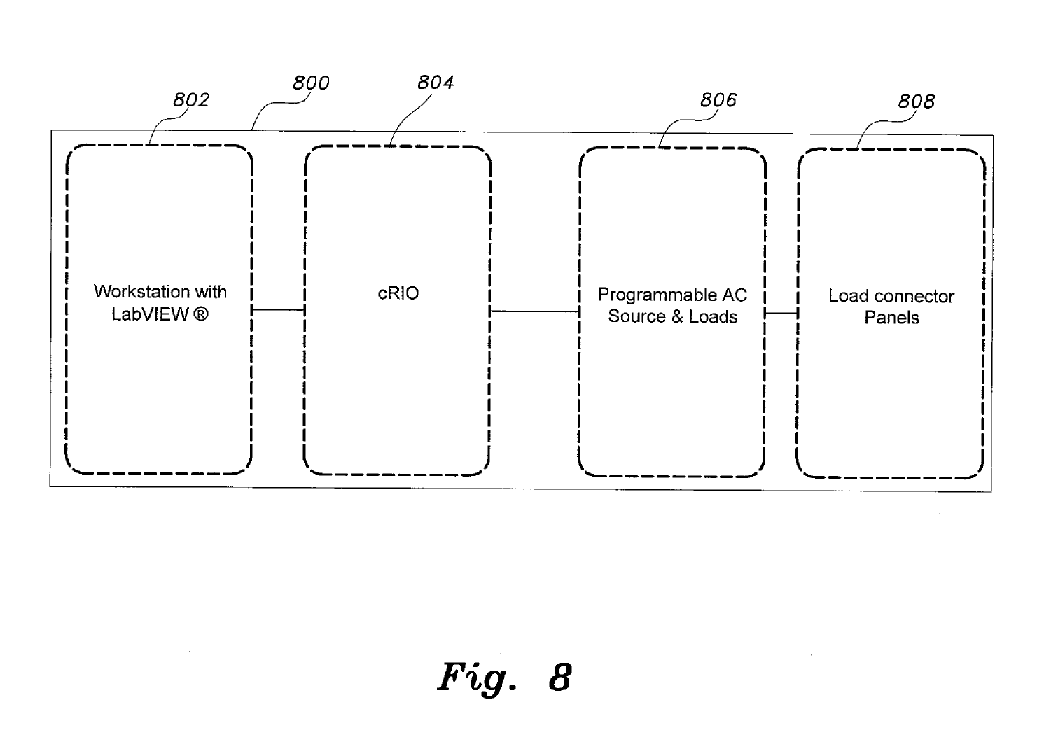

As shown in FIG. 8, an embodiment of a wavelet transform system 800 for voltage events detection and classification is illustrated, as can implement embodiments of wavelet transform methods for voltage events detection and classification. The system 800 includes, for example, a workstation 802, such as running LabVIEW® 2011, a National Instrument CompactRIO-9024 (cRIO) controller 804, a programmable AC source and programmable electronic loads component 806, and load connector panels component 808, such as housing current transformers with load connectors.

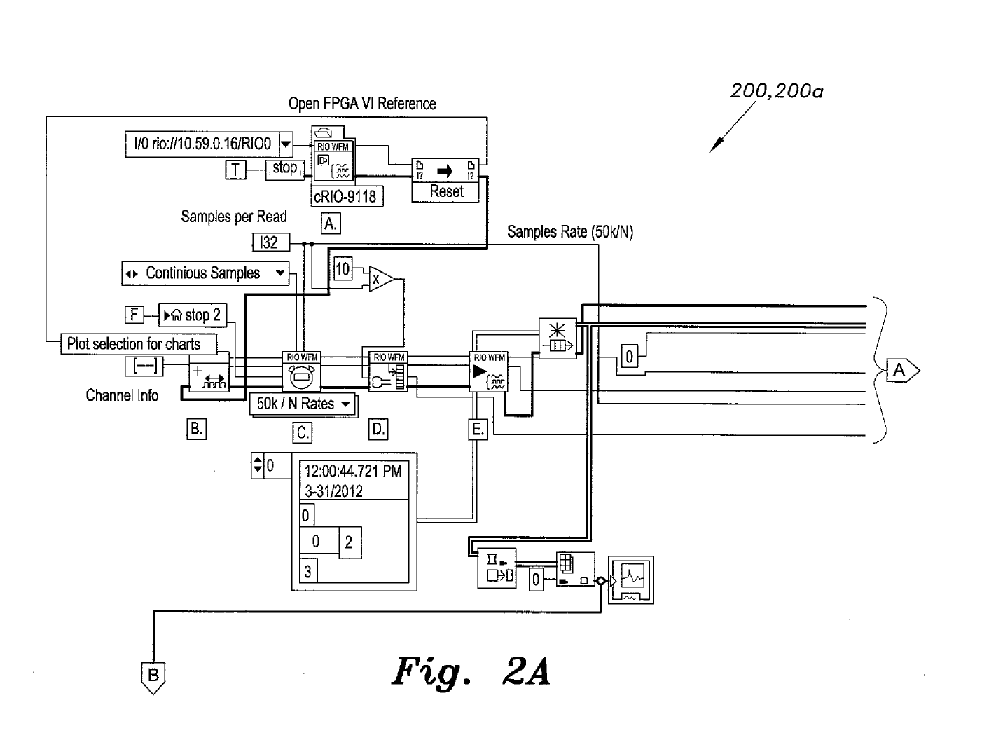

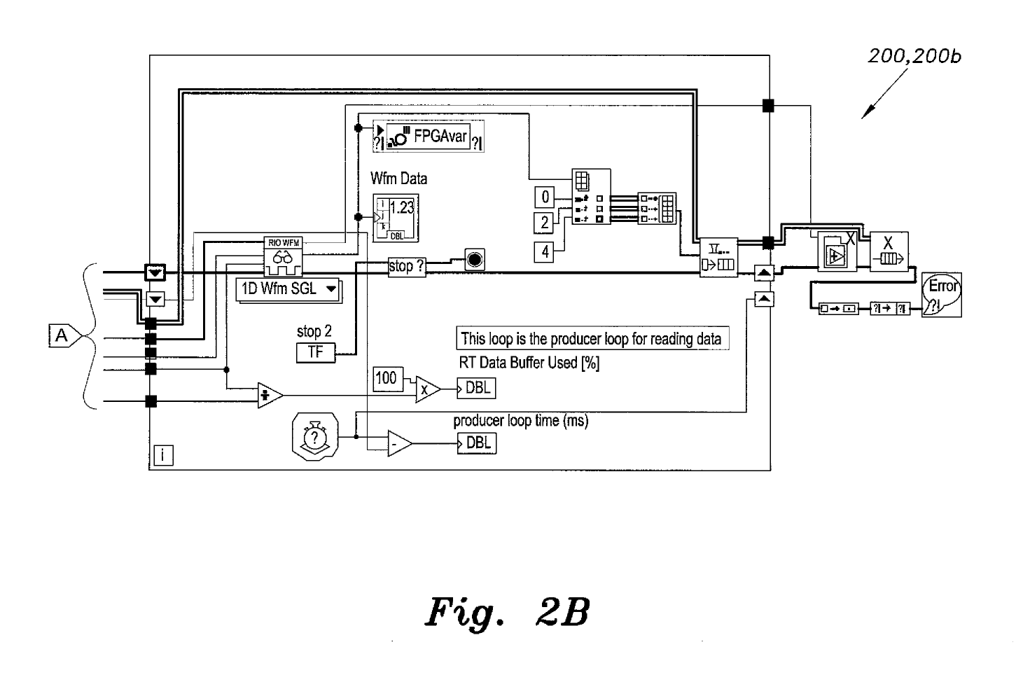

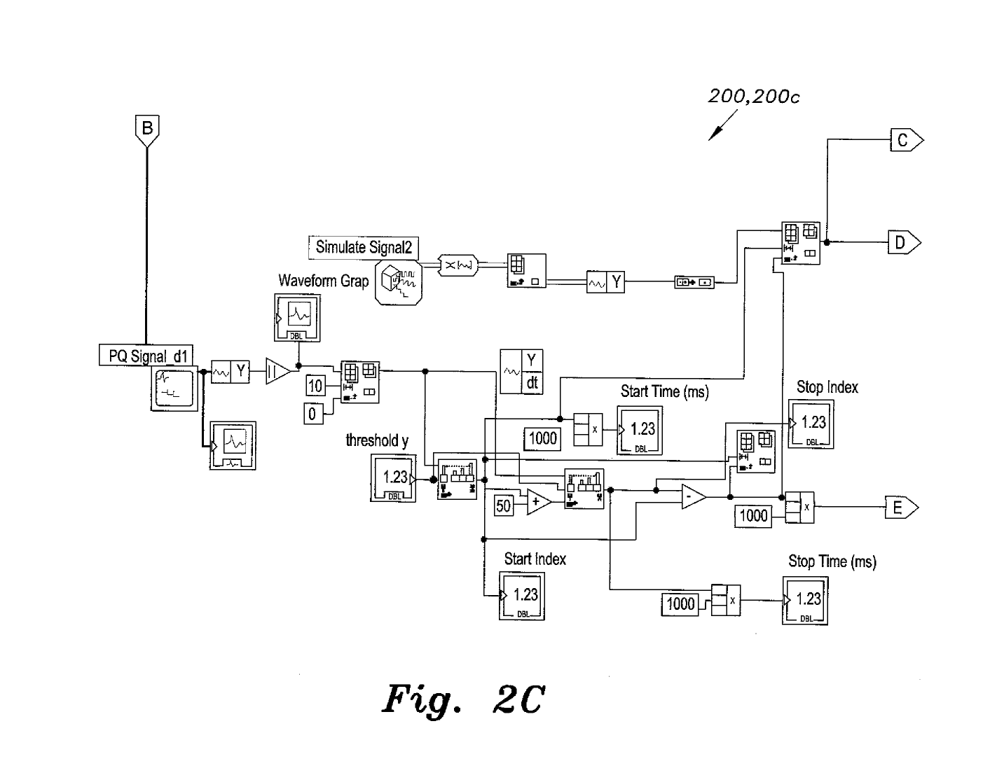

Also, referring to FIGS. 2A-2D, system components 200a-200d that collectively form a virtual instrument (VI) block diagram 200 of a voltage monitoring system, respectively, as can be implemented in the voltage monitoring system 800 in implementing embodiments of wavelet transform systems and methods for voltage events detection and classification are illustrated.

The Programmable AC source and programmable electronic loads component 806 can provide relatively powerful functions to simulate voltage disturbance conditions, such as interruption, sag, and swell. The programmable electronic loads can simulate loading conditions under different crest factor and varying power factors with real time compensation even when the voltage waveform is distorted. Therefore, the features of the programmable AC source and programmable electronic loads component 806 can provide a real world simulation capability and can prevent overstressing to enhance relatively reliable and unbiased test results.

The cRIO controller 804 typically can include three main parts. A first part of the cRIO controller 804 includes an industrial processor that can deterministically execute LabVIEW® Real-Time applications and can offer multi-rate control, execution tracing, onboard data logging, and communication with peripherals, for example. A second part of the cRIO controller 804 includes a reconfigurable field-programmable gate array (FPGA) Chassis that is a center of an embedded system architecture. The reconfigurable input/output (I/O) (RIO) FPGA is connected to the I/O modules for relatively high-performance access to the I/O circuitry of various modules in the system 800 and can provide relatively unlimited timing, triggering, and synchronization flexibility, for example. A third part of the cRIO controller 804 includes I/O Modules, such as the NI-9225 module, which can measure directly from the line up to 300 V rms and the NI-9227 module which is a 4 channel 5 A rms current measurement module. Current transformers (100/5 A) can be used to measure the load currents directly with this module.

In implementing embodiments of wavelet transform systems and methods for voltage events detection and classification in an embodiment of a wavelet transform system 800 for voltage events detection and classification, LabVIEW® 2011 was selected as a graphical based programming language. Algorithms were developed to read data at the specified sampling frequency and process it using the cRIO 804 real-time controller for voltage monitoring.

It is understood that embodiments of wavelet transform systems and methods for voltage events detection and classification can include software or firmware code executing on a computer, a microcontroller, a microprocessor, or a DSP processor; state machines implemented in application specific or programmable logic; or various other forms without departing from the spirit and scope of embodiments of wavelet transform systems and methods for voltage events detection and classification described herein. Embodiments of wavelet transform systems and methods for voltage events detection and classification can be provided and implemented as a computer program, which includes a non-transitory machine-readable medium having stored thereon instructions that can be used to program a computer (or other electronic devices) to perform processes according to embodiments of wavelet transform systems and methods for voltage events detection and classification. The machine-readable medium can include, but is not limited to, floppy diskettes, optical disks, CD-ROMs, and magneto-optical disks, ROMs, RAMS, EPROMs, EEPROMs, magnetic or optical cards, flash memory, or other type of media or machine-readable medium suitable for storing electronic instructions.

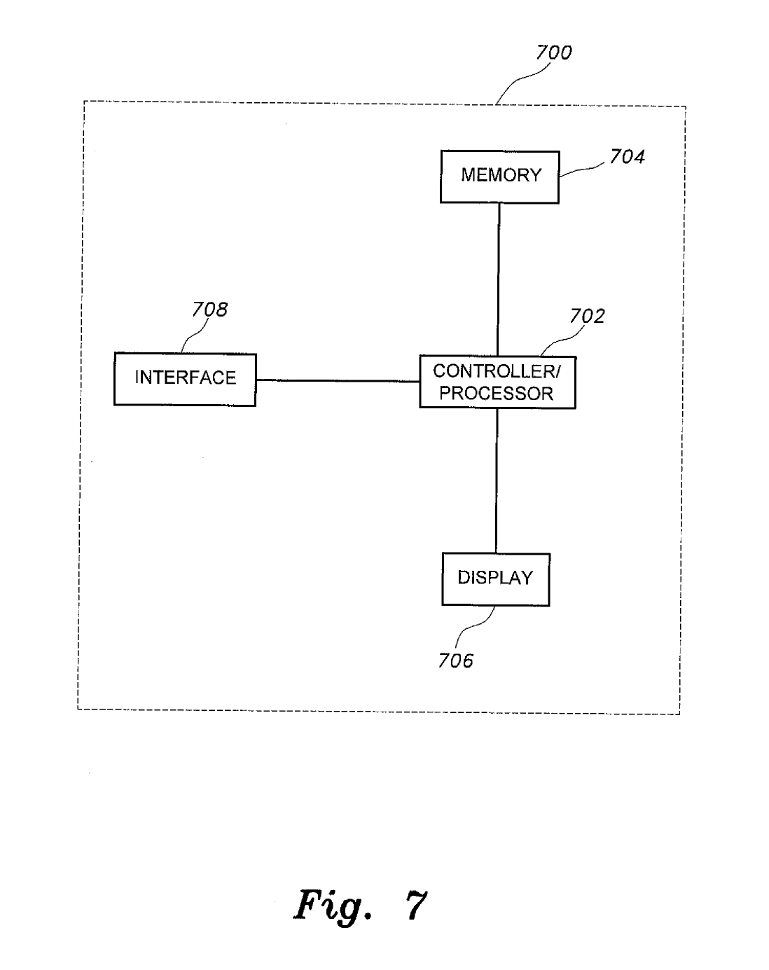

Referring to FIG. 7, it is to be understood that a processing system, such as exemplary processing system 700, shown in FIG. 7 is a generalized processing system, as can be included in a computer implemented device, for implementing embodiments of wavelet transform systems and methods for voltage events detection and classification, such as can be implemented in the voltage monitoring system 800 implementing the virtual instrument block diagram 200 of a voltage monitoring system. It should be understood that the generalized processing system 700 may represent, for example, a stand-alone computer, computer terminal, portable computing device, networked computer or computer terminal, or networked portable device. Data may be entered into the system 700 by the user via any suitable type of user interface 708, and may be stored in computer readable memory 704, which may be any suitable type of computer readable and programmable memory, Calculations are performed by the controller/processor 702, which may be any suitable type of computer processor, and may be displayed to the user on the display 706, which may be any suitable type of computer display, for example.

The controller/processor 702 may be associated with, or incorporated into, any suitable type of computing device, for example, a personal computer or a programmable logic controller, field programmable gate array (FPGA), and the like. The display 706, the processor 702, the memory 704, and any associated computer readable media are in communication with one another by any suitable type of data bus, as is well known in the art. Exemplary processing system 700 may be used for computations during execution and implementation of embodiments of wavelet transform systems and methods for voltage events detection and classification. It should be understood that processor system 700 exemplifies the type of processor or processors that may reside or be implemented in the system 800 to effect means for executing embodiments of wavelet transform systems and methods for voltage events detection and classification.

For example, processes executing embodiments of wavelet transform systems and methods for voltage events detection and classification may reside in workstation 802 and/or Compact RIO controller 804 in a single processing or distributed processing environment with relatively no limitation on a number of processing cores or threads which may be used. The exemplary processing system 700 can allow processor 702 to execute sequences of instructions, such as in the system 800, which provide the means for computing a first result

$${‖ ( {d}_{{j}_{0} k} ) ‖}_{{Δ}_{{j}_{0}}}$$

of a finest detail level of a pure signal based on wavelet coefficients [symbol] of the pure signal, means for computing a second result

$${‖ ( {\tilde{d}}_{{j}_{0} k} ) ‖}_{{Δ}_{{j}_{0}}}$$

of a coarsest level of a disturbance signal based upon wavelet coefficients (\tilde{d}ⱼₖ)_{k ε Δ}_{ⱼ} of the disturbance signal, and means for computing a third result r relating the second result of the coarsest level to the first result of the finest detail level, the means for computing the first result, the second result and the third result include means for calculating a first formula characterized by the relation,

$${‖ ( {d}_{{j}_{0} k} ) ‖}_{{Δ}_{{j}_{0}}} = {( {\sum }_{k ∈ {Δ}_{{j}_{0}}} {d}_{{j}_{0} k}^{2} )}^{\frac{1}{2}} ,$$

means for calculating a second formula characterized by the relation,

$${‖ ( {\tilde{d}}_{{j}_{0} k} ) ‖}_{{Δ}_{{j}_{0}}} = {( {\sum }_{k ∈ {Δ}_{{j}_{0}}} {\tilde{d}}_{{j}_{0} k}^{2} )}^{\frac{1}{2}} ,$$

and means for calculating a third formula characterized by the relation,

$$r = \frac{{‖ ( {\tilde{d}}_{{j}_{0} k} ) ‖}_{{Δ}_{{j}_{0}}}}{{‖ ( {d}_{{j}_{0} k} ) ‖}_{{Δ}_{{j}_{0}}}} .$$

Moreover, sequences of instruction executable within processing system 700, such as implemented in the system 800, also can provide the means for determining a no fault event type based on the relation, (1−ε)≦r≦(1+ε) where ε is a preassigned threshold. Additional sequences of instruction executable within the processing system 700, as can be implemented in the system 800, can provide the means for determining a swell fault event type based on the relation, r>(1+ε). Moreover, there are instructions executable within processing system 700, as can be implemented in the system 800, which can provide the means for determining a sag fault event type based on the relation, ε≦r<(1−ε). Processing system 700 also includes sequences of instructions executable by processor 702, as can be implemented in the system 800, which provide means for determining, when r<ε, that an interruption fault event type has occurred based on the computation of: Fⱼ=Σ_{k εΔ}_{ⱼ} dⱼₖ \tilde{d}ⱼₖ, j=1, . . . j₀−1 and the satisfaction of the relation, Σⱼ₌₁^{J}Fⱼ²≦ε². Further sequences of instruction executable by processor 702 of processing system 700, as can be implemented in the system 800, can provide the means for characterizing start times, stop times and durations of the voltage events, for example.

Examples of computer readable media in which the aforementioned sequences of instruction are stored thereon include a magnetic recording apparatus, non-transitory computer readable storage memory, an optical disk, a magneto-optical disk, and/or a semiconductor memory (for example, RAM, ROM, etc.). Examples of magnetic recording apparatus that may be used in addition to memory 704, or in place of memory 704, include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW.

A conventional calculation method of a rms voltage based on DWT in power system can be calculated as follows.

$${V}_{rm s} = \sqrt{{V}_{{j}_{0}}^{2} + {\sum }_{j \leq {j}_{0}} {V}_{j}^{2}} , \qquad ( 1 )$$

where the jⱼ₀ is the rms voltage value of the coarsest approximation wavelet decomposition level j₀ (a lowest frequency subband) which includes the fundamental frequency and {Vⱼ} are the set of rms voltage values of each detail wavelet decomposition level j higher than or equal to j₀. The conventional method of rms voltage calculation based on DWT typically utilizes all the detail wavelet decomposition levels, as well as the coarsest approximation wavelet decomposition level, to calculate the rms voltage as given in (20).

However, unlike the conventional method of rms voltage calculation, embodiments of wavelet transform systems and methods for voltage events detection and classification typically can utilize a single level to accomplish the calculation of rms voltage, which is a coarsest approximation level that includes the fundamental frequency, for example. According to the execution manner of embodiments of wavelet transform systems and methods for voltage events detection and classification, as compared to the conventional methods, embodiments of wavelet transform systems and methods for voltage events detection and classification typically have less complexity than the conventional methods.

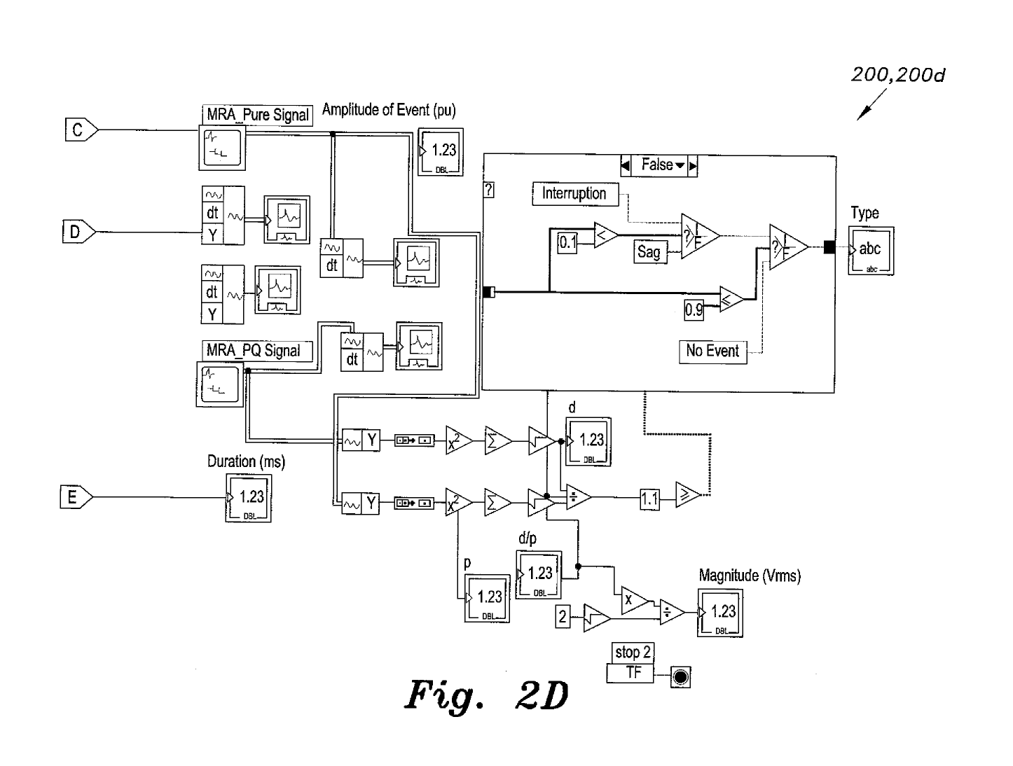

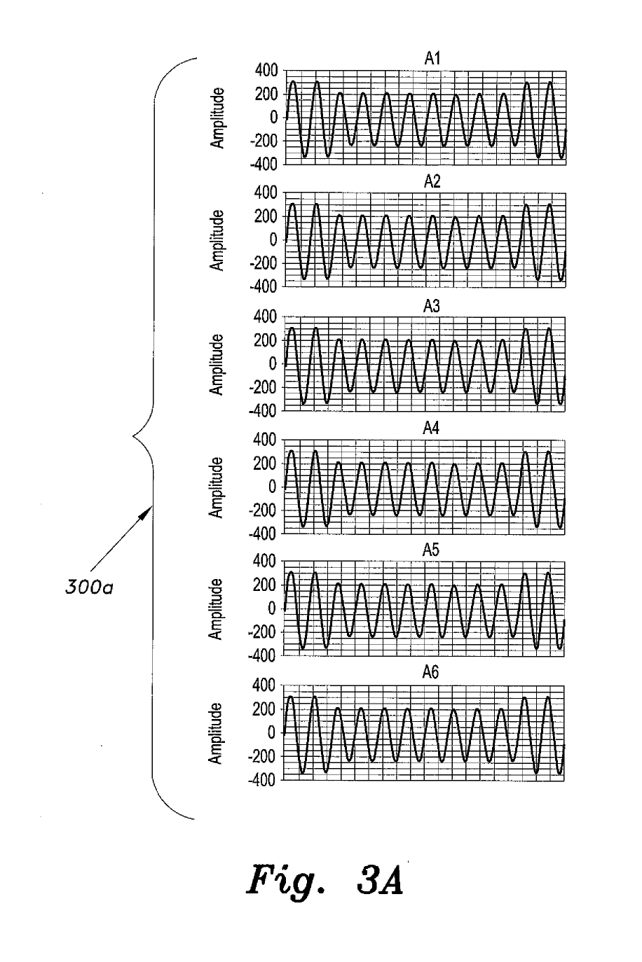

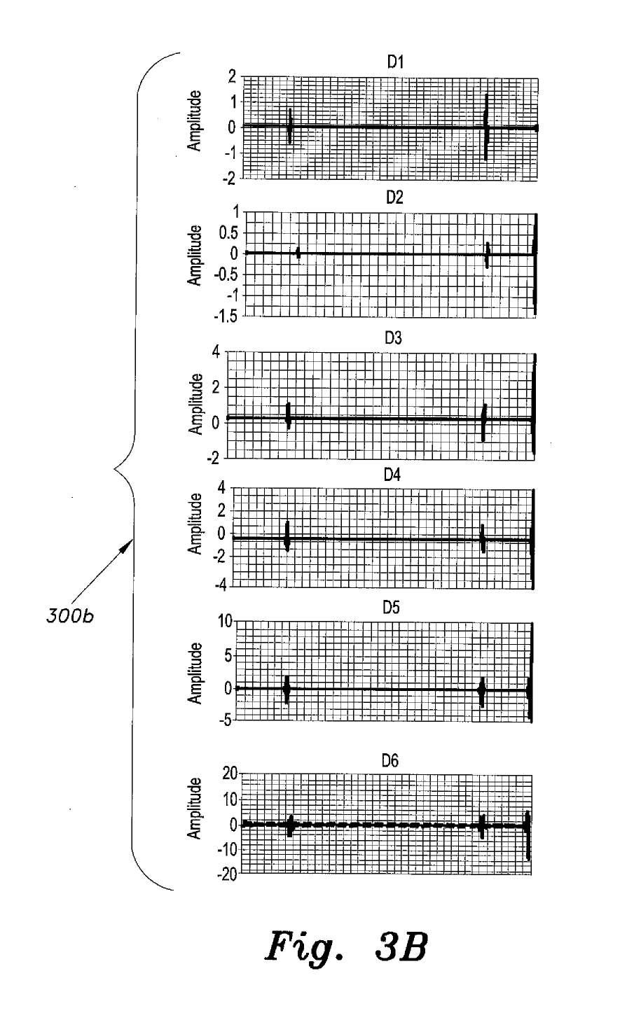

For example, a conventional method of rms voltage calculation based on DWT has been applied on test voltage signal that consist of 12 cycles, with 60 hertz (Hz), 220 V and sampling frequency equals to 10 kilohertz (kHz) (166 samples/cycle). The applied event is voltage sag with a duration equal to 8 cycles (132.8 milliseconds (ms)) that occurs at 33.2 ms and ends at 166 ms and its magnitude is 154Vₘₛ. Oscillographic, plots 300a and 300b of FIGS. 3A and 3B, respectively, display the first six decomposition approximation levels (A1-A6) and detail levels (D1-D6) of the test signal. According to (20), Vⱼ₀ represents the rms voltage of the sixth approximation level (A6) and {Vⱼ} represents {V_{D1}, V_{D2} . . . V_{D6}}. Therefore, (20) can be rewritten as:

$${V}_{r m s} = \sqrt{{V}_{A 6}^{2} + {\sum }_{j = 1}^{6} {V}_{Dj}^{2}} . \qquad ( 2 )$$

It is observed from the simulation results that the accuracy of the estimated voltage magnitude for different voltage events using the conventional method, as compared to using embodiments of wavelet transform systems and methods for voltage events detection and classification, are relatively similar, such as shown in Table 3. However, in contrast, the average execution time for ten runs of the conventional method for analyzing data of one window (12 cycles) is 51 ms, while the average execution time for ten runs implemented using embodiments of wavelet transform systems and methods for voltage events detection and classification for analyzing the same data size is 11 ms. Hence, embodiments of wavelet transform systems and methods for voltage events detection and classification can save more than 78% from the processing time to accomplish the analysis of the voltage events over the conventional method. Such saving in processing time can make embodiments of wavelet transform systems and methods for voltage events detection and classification more suitable for online implementation than the conventional method, for example.

TABLE 3
Comparison of wavelet transform method (Wtm.) and the conventional
method (Conv.) for voltage events detection and classification
accuracy for voltage events characterization

| | Voltage Event | | | | | |
|---|---|---|---|---|---|---|
| Event | Interruption | | Sag | | Swell | |
| Characterization | Conv. | Wtm. | Conv. | Wtm. | Conv. | Wtm. |
| The Start Time | 99.8 | 99.8 | 99.8 | 99.8 | 99.8 | 99.8 |
| The Stop Time | 99.7 | 99.7 | 99.7 | 99.7 | 99.6 | 99.6 |
| The Magnitude | 98.7 | 99.2 | 99.9 | 99.8 | 98.8 | 99.9 |

The test signal that is utilized to evaluate the experimental real-time performance of embodiments of wavelet transform systems and methods for voltage events detection and classification is generated by the programmable AC source and programmable electronic loads component 806. The test signals consist of 12 cycles with a rated voltage equal to 220 V, 60 Hz and a sampling frequency equal to 10 kHz (166 samples/cycle). The event duration for each considered case is 8 cycles (132.8 ms) that occurs at 33.2 ms and ends at 166 ms. The experiments include the voltage interruption, sag, and swell. Each event has been carried out for three times.

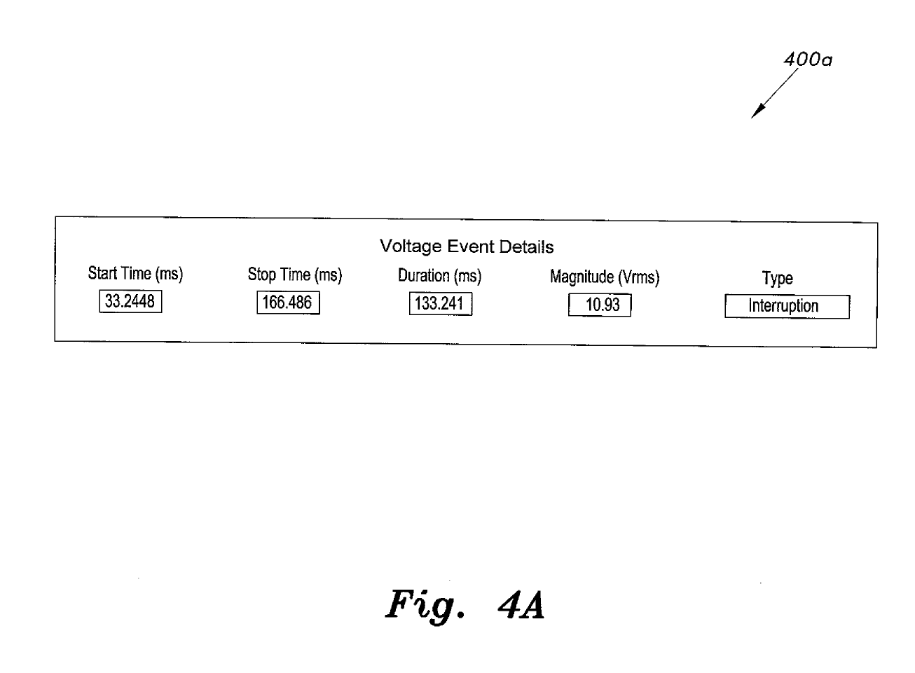

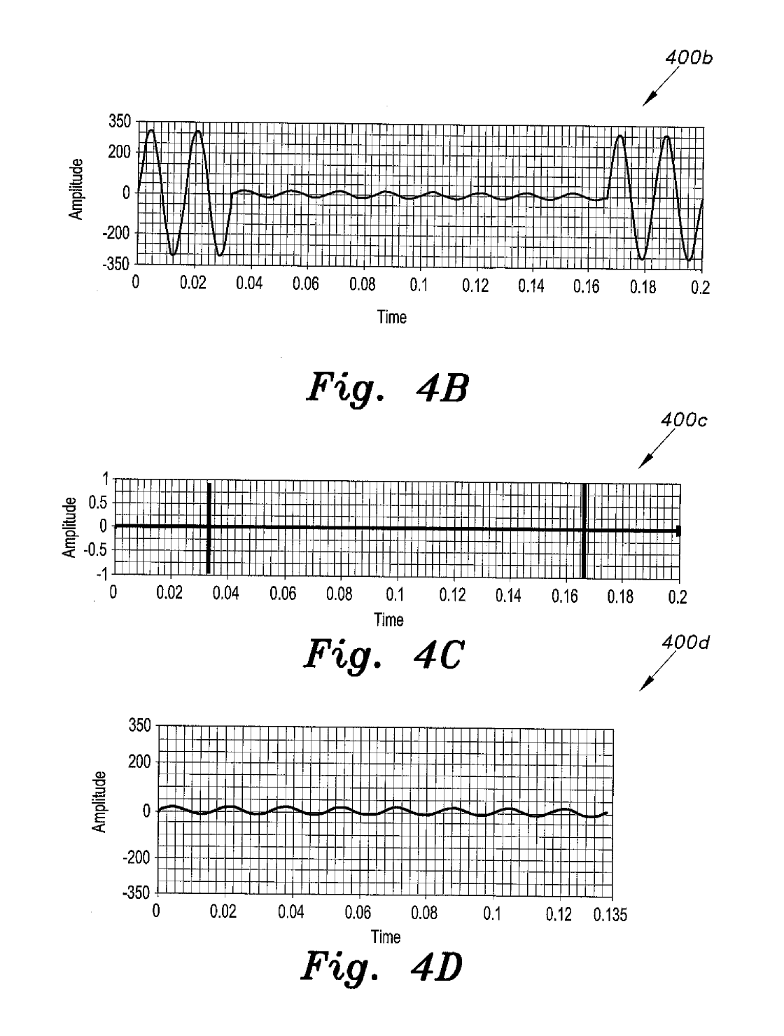

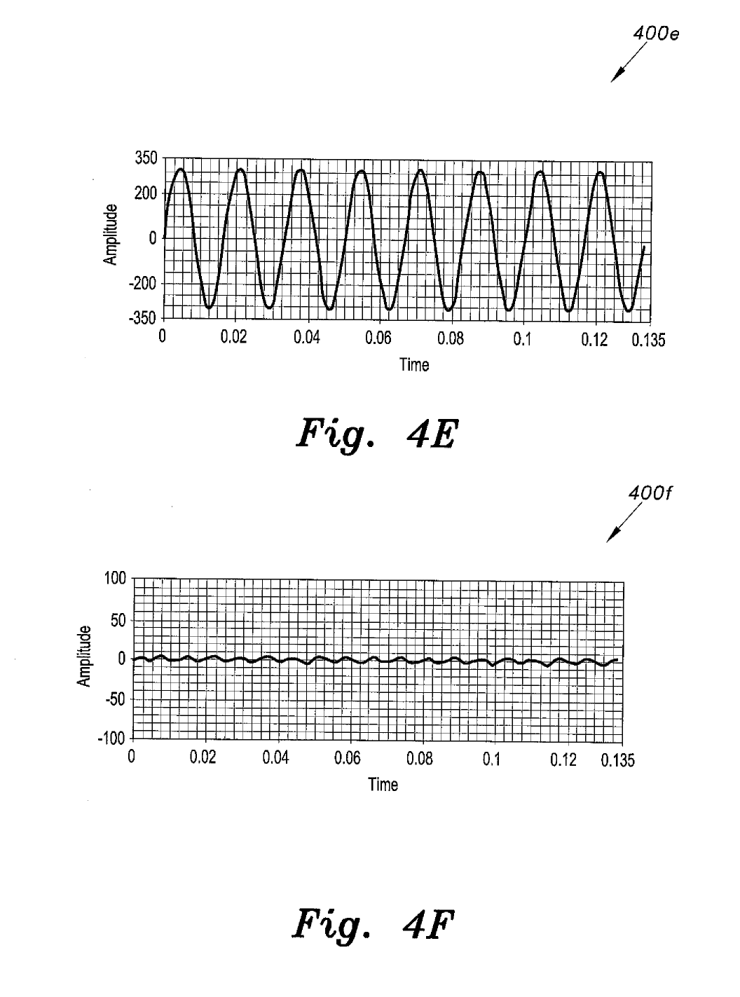

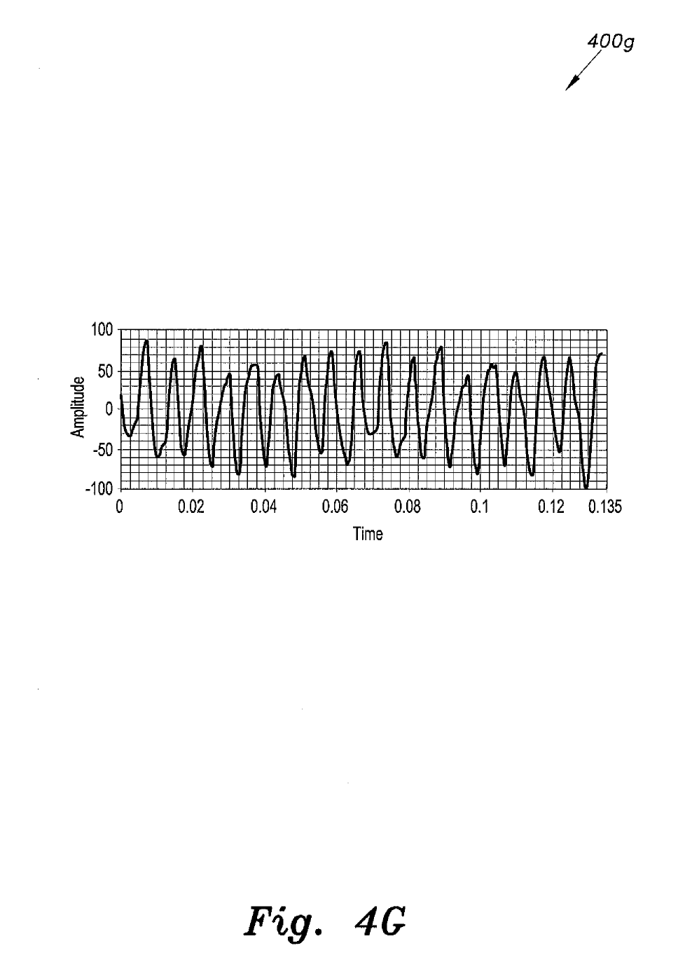

Referring to FIGS. 4A-4G, the results of the voltage interruption, and the voltage value during the interruption is 11 V (0.05 per unit (pu)) are illustrated. Screenshot 400a of FIG. 4A shows the details of the voltage event that is detected, characterized, and classified by embodiments of wavelet transform systems and methods for voltage events detection and classification, such as the start time of the event that has been estimated at a time equal to 33.24 ms with an accuracy reach to more than 99.8%, the stop time of the event that has been estimated at a time equal to 166.49 ms with an accuracy reach to 99.7%, the event duration is approximately 133.24 ms and is calculated with an accuracy more than 99.6%, the estimated magnitude of the voltage interruption event is 10.93 V that has been estimated with an accuracy reach to more than 99.3%, as well as embodiments of the wavelet transform systems and methods for voltage events detection and classification are utilized to classify a voltage event type.

Oscillographic plot 400b of FIG. 4B shows a measured waveform corresponding to the monitoring system behavior in response to voltage interruption in embodiments of wavelet transform systems and methods for voltage events detection and classification. The first and the second peaks of the coefficients of the first detail level (D1) have been utilized to detect the details of the voltage events as shown in oscillographic plot 400c of FIG. 4C. The waveforms of the distorted and pure voltage signals within the event duration are shown in oscillographic plot 400d of FIG. 4D and oscillographic plot 400e of FIG. 4E, respectively. Oscillographic plots 400f of FIG. 4F and 400g of FIG. 4G show the coarsest approximation level (A6) of the distorted and pure voltage signals within the voltage event duration, respectively.

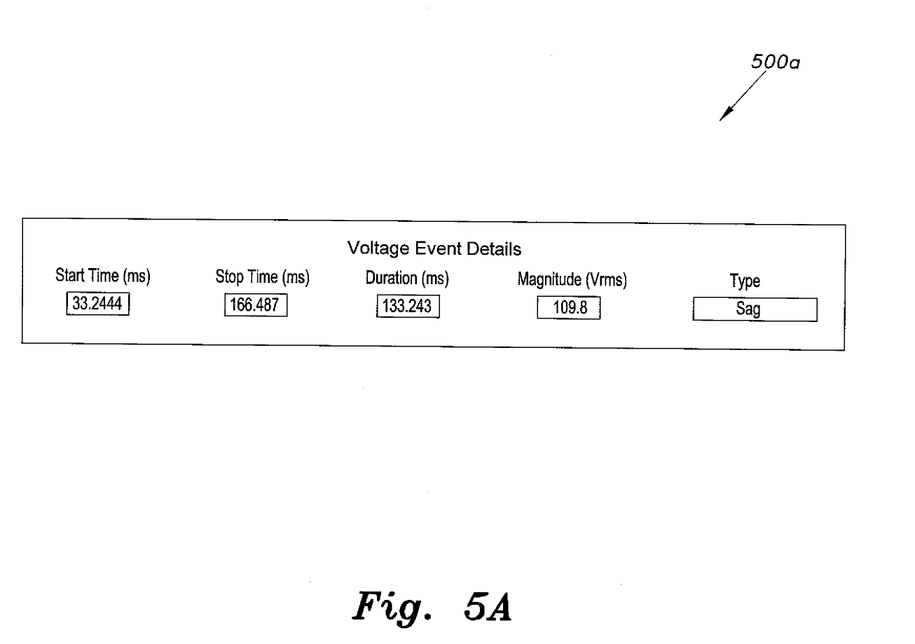

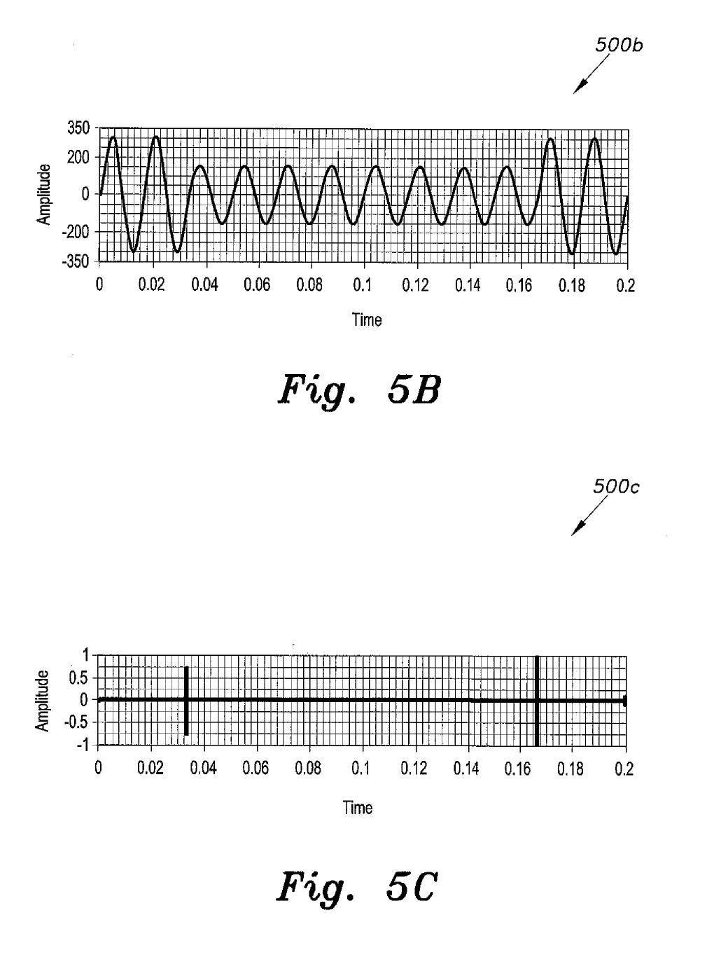

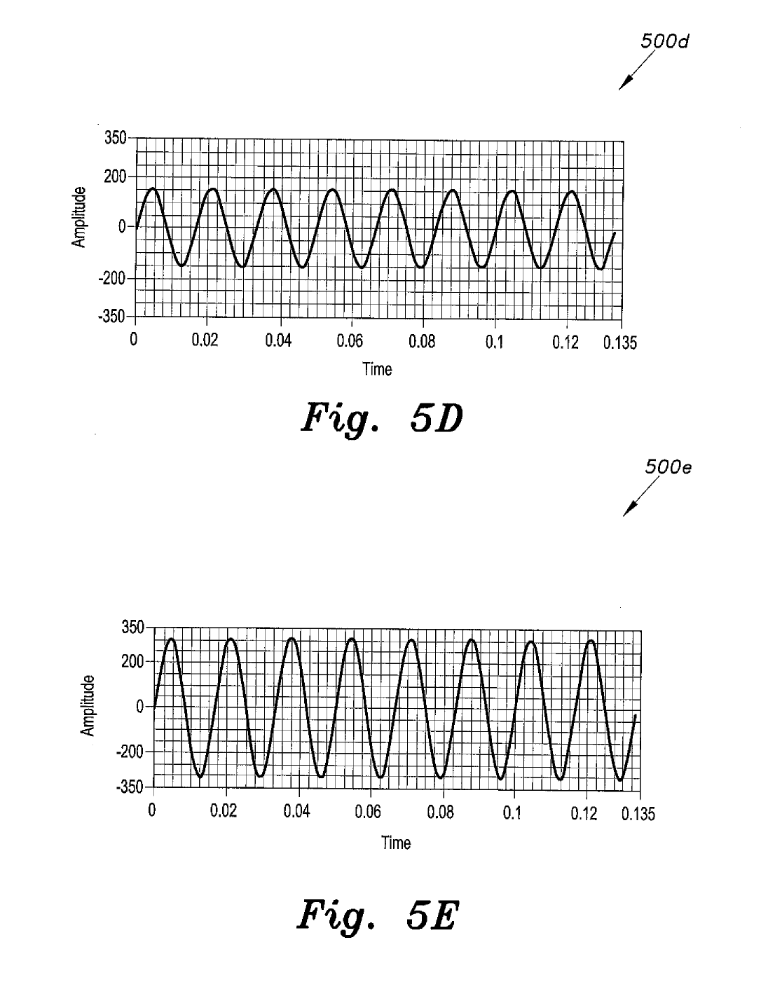

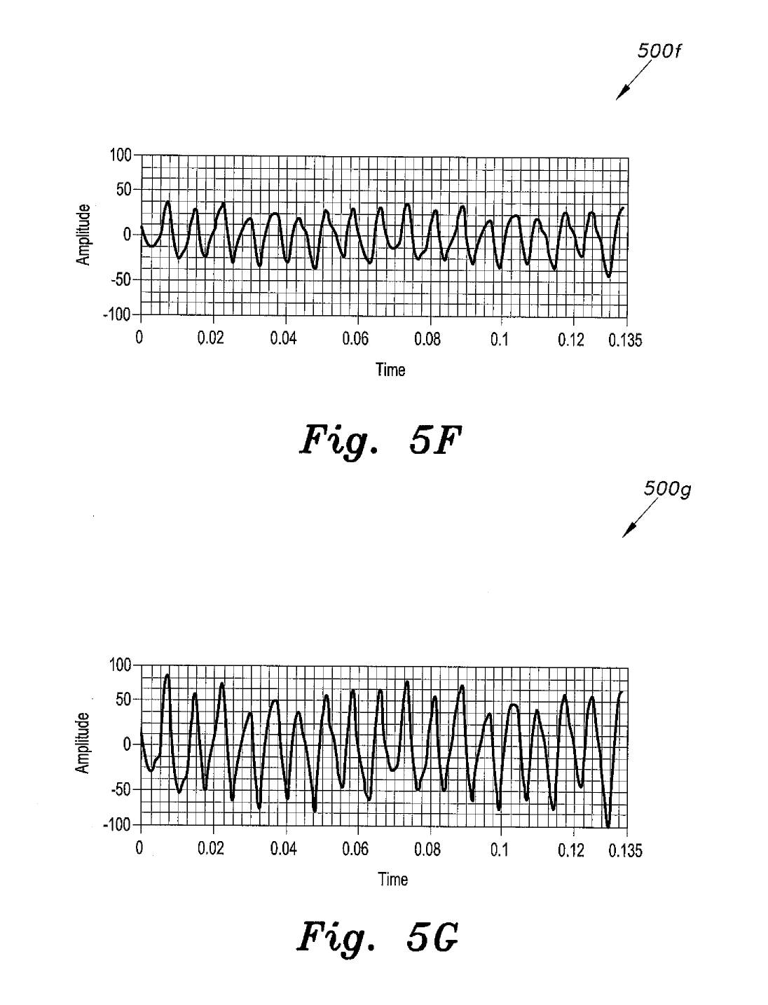

Referring to FIGS. 5A-5G, the results of the voltage sag with value equals to 110 V (0.5 pu) are illustrated. Screenshot 500a of FIG. 5A shows the details of the voltage sag that has been estimated using embodiments of wavelet transform systems and methods for voltage events detection and classification, such as the event start time is estimated at a time equal to 33.24 ms, the stop time of the event that has been estimated at a time equal to 166.49 ms, the event duration is approximately 133.24 ms, and the estimated magnitude of the voltage sag event is 109.8 V. These details of voltage sag have been estimated using embodiments of wavelet transform systems and methods for voltage events detection and classification with an accuracy reach to more than 99.7%, for example. Oscillographic plot 500b of FIG. 5B shows a measured waveform corresponding to the monitoring system behavior in response to voltage sag. Oscillographic plots 500c-500g of FIGS. 5C through 5G, respectively, show the waveforms that are used to characterize and classify the voltage sag, for example.

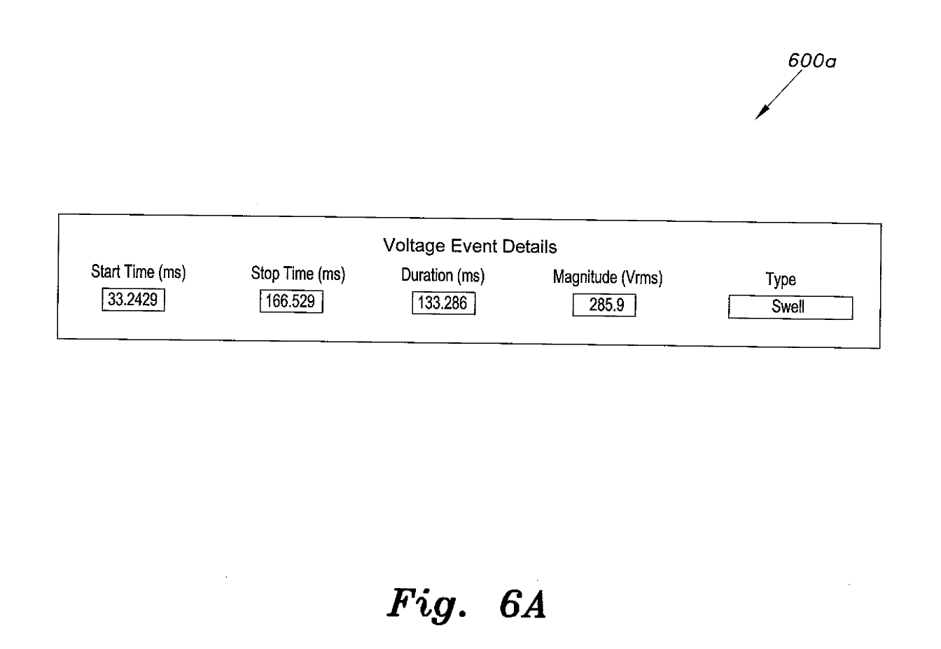

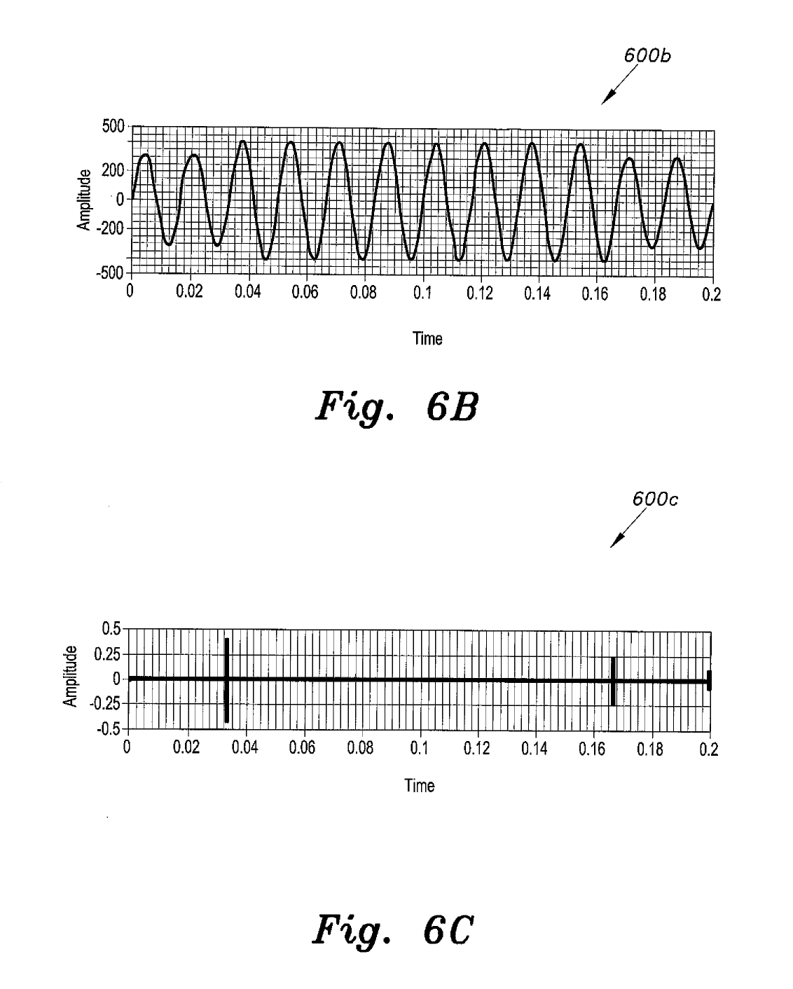

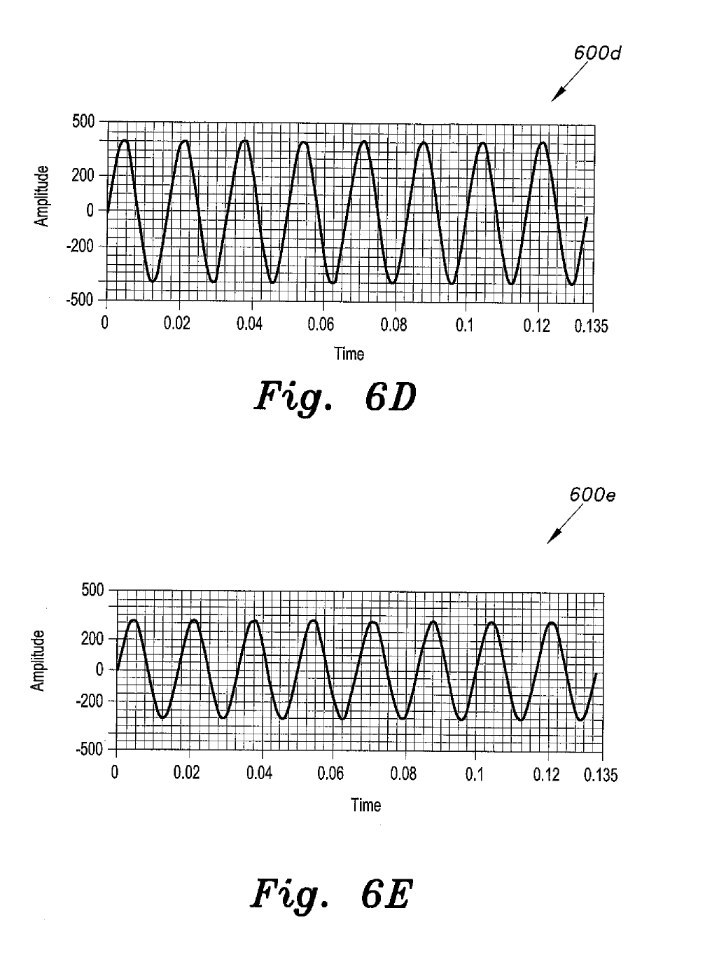

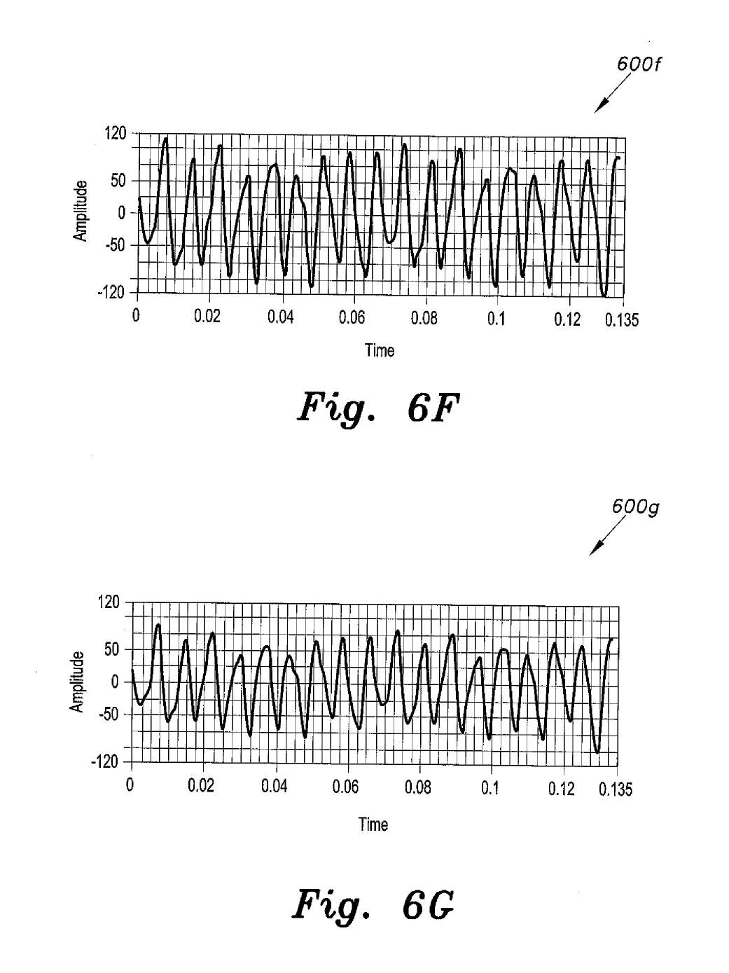

Referring to FIGS. 6A-6G, the results of voltage events detection and classification using embodiments of wavelet transform systems and methods for voltage events detection and classification for detecting, characterizing, and classifying the voltage swell, with a value equal to 286 V (1.3 pu), are illustrated. Screenshot 600a of FIG. 6A shows the estimated details of the voltage swell, such as the start time, the stop time and the duration are 33.24 ms, 166.53 ms, and 133.29 ms, respectively, and the estimated magnitude of the voltage swell is 285.9 V. These details of voltage swell have been estimated using embodiments of wavelet transform systems and methods for voltage events detection and classification with a minimum accuracy reach to more than 99.6%, for example. Plot 600b of FIG. 6B shows a measured waveform corresponding to the monitoring system behavior in response to the voltage swell. The oscillographic plots 600c-600g of FIGS. 6C-6G, respectively, show the waveforms that are used to characterize and classify the voltage swell.

As noted, the accuracy measures of embodiments of wavelet transform systems and methods for voltage events detection and classification in characterization of the voltage events in terms of the start time, the end time, and the magnitude are given in Table 3. From the foregoing discussion in relation to FIGS. 1-8, comparing the performance of embodiments of wavelet transform systems and methods for voltage events detection and classification to the conventional method given in Eq. (20), it is evident that the relative accuracy of embodiments of wavelet transform systems and methods for voltage events detection and classification are typically generally better than that of the conventional method. Moreover, embodiments of wavelet transform systems and methods for voltage events detection and classification typically utilize less information than the conventional method for the voltage events detection and classification.

Embodiments of wavelet transform systems and methods for voltage events detection and classification based on a multi-resolution analysis utilize a first detail level and a last approximation level to detect and classify the voltage events. A laboratory setup of implementing embodiments of wavelet transform systems and methods for voltage events detection and classification has been developed and built using a LabVIEW® platform. The experimental real-time results show the relative effectiveness and robustness of embodiments of wavelet transform systems and methods for voltage events detection and classification in detection the start time, the end time, and the duration, as well as the classification of the various voltage events considered. Moreover, embodiments of wavelet transform systems and methods for voltage events detection and classification are relatively less complex and relatively faster than the conventional methods.

It is to be understood that embodiments of wavelet transform systems and methods for voltage events detection and classification are not limited to the embodiments described above, but encompasses any and all embodiments within the scope of the following claims.

We claim:

1. A computer implemented wavelet transform method for voltage events detection and classification, comprising the steps of:
executing, with a processor, a program stored in a memory of a computer implemented device, the program directing the computer implemented device to perform the following:
computing a first result
$${‖ ( {d}_{{j}_{0} k} ) ‖}_{{Δ}_{{j}_{0}}}$$
of a finest detail level of a pure signal based on wavelet coefficients [symbol] of said pure signal, computing a second result
$${‖ ( {\tilde{d}}_{{j}_{0} k} ) ‖}_{{Δ}_{{j}_{0}}}$$
of a coarsest level of a disturbance signal based upon wavelet coefficients (\tilde{d}ⱼₖ)_{k ε Δ}_{ⱼ} of said disturbance signal, and computing a third result r relating the second result of the coarsest level to the first result of the finest detail level, by calculation of:
a first formula calculating the first result of the finest detail level of said pure signal characterized by the relation:
$${‖ ( {d}_{{j}_{0} k} ) ‖}_{{Δ}_{{j}_{0}}} = {( {\sum }_{k ∈ {Δ}_{{j}_{0}}} {d}_{{j}_{0} k}^{2} )}^{\frac{1}{2}} ;$$
a second formula calculating the second result of the coarsest level of said disturbance signal characterized by the relation:
$${‖ ( {\tilde{d}}_{{j}_{0} k} ) ‖}_{{Δ}_{{j}_{0}}} = {( {\sum }_{k ∈ {Δ}_{{j}_{0}}} {\tilde{d}}_{{j}_{0} k}^{2} )}^{\frac{1}{2}} ;$$
and
a third formula calculating the third result r relating the second result of the coarsest level to the first result of the finest detail level, characterized by the relation:
$$r = \frac{{‖ ( {\tilde{d}}_{{j}_{0} , k} ) ‖}_{{Δ}_{{j}_{0}}}}{{‖ ( {d}_{{j}_{0} k} ) ‖}_{{Δ}_{{j}_{0}}}} ;$$
selectively determining a no fault event type based on the relation:
(1−ε)≦r≦(1+ε),
where ε is a preassigned threshold;
selectively determining a swell fault event type based on the relation:
r>(1+ε);
selectively determining a sag fault event type based on the relation:
ε≦r<(1−ε); and
selectively determining, when r<ε, that an interruption fault event type has occurred based on the computation of:
$${F}_{j} = {\sum }_{k ∈ {Δ}_{j}} {d}_{jk} {\tilde{d}}_{jk} , j = 1 , … , {j}_{0} - 1$$
and the satisfaction of the relation:
$${\sum }_{j = 1}^{J} {F}_{j}^{2} \leq {ɛ}^{2} ,$$
wherein (dⱼₖ) and (\tilde{d}_{j′k′}) are orthogonal sequences, (\tilde{d}ⱼₖ)_{k ε Δ}_{ⱼ} are wavelet coefficients of the disturbance signal at the coarsest approximation level j₀ over the disturbance interval I_{d}, where Δⱼ={k: supp ψⱼₖ⊂I_{d}), k corresponds to the wavelet coefficients at a level, supp ψⱼₖ corresponds to a mother wavelet, and [symbol] are wavelet coefficients of the pure signal at the scale level j and [symbol] is a level group, and Fⱼ corresponds to a result in the interruption fault event type determination.

2. The computer implemented wavelet transform method for voltage events detection and classification according to claim 1, wherein the finest detail level is utilized to detect a start time, an end time, and a duration of a voltage event, and the coarsest level is utilized to classify a voltage event.

3. A voltage events detection and classification system, comprising:
a computer implemented device including a processor and a memory, a program stored in the memory to direct the computer implemented device to perform voltage events detection and classification, the computer implemented device including:
means for computing a first result
$${‖ ( {d}_{{j}_{0} k} ) ‖}_{{Δ}_{{j}_{0}}}$$
or a finest detail level of a pure signal based on wavelet coefficients [symbol] of said pure signal, for computing a second result
$${‖ ( {\tilde{d}}_{{j}_{0} k} ) ‖}_{{Δ}_{{j}_{0}}}$$
of a coarsest level of a disturbance signal based upon wavelet coefficients (\tilde{d}ⱼₖ)_{k ε Δ}_{ⱼ} of said disturbance signal, and for computing a third result r relating the second result of the coarsest level to the first result of the finest detail level, said first result, second result and third result computing means including:
means for calculating the first result of the finest detail level of said pure signal characterized by the relation:
$${‖ ( {d}_{{j}_{0} k} ) ‖}_{{Δ}_{{j}_{0}}} = {( {\sum }_{k ∈ {Δ}_{{j}_{0}}} {d}_{{j}_{0} k}^{2} )}^{\frac{1}{2}} ;$$
means for calculating the second result of the coarsest level of said disturbance signal characterized by the relation:
$${‖ ( {\tilde{d}}_{{j}_{0} k} ) ‖}_{{Δ}_{{j}_{0}}} = {( {\sum }_{k ∈ {Δ}_{{j}_{0}}} {\tilde{d}}_{{j}_{0} k}^{2} )}^{\frac{1}{2}} ;$$
and
means for calculating the third result r relating the second result of the coarsest level to the first result of the finest detail level, characterized by the relation:
$$r = \frac{{‖ ( {\tilde{d}}_{{j}_{0} k} ) ‖}_{{Δ}_{{j}_{0}}}}{{‖ ( {d}_{{j}_{0} k} ) ‖}_{{Δ}_{{j}_{0}}}} ;$$
means for determining a no fault event type based on the relation:
(1−ε)≦r≦(1+ε),
where ε is a preassigned threshold;
means for determining a swell fault event type based on the relation:
r>(1+ε);
means for determining a sag fault event type based on the relation:
ε≦r<(1−ε); and
means for determining, when r<ε, that an interruption fault event type has occurred based on the computation of:
$${F}_{j} = {\sum }_{k ∈ {Δ}_{j}} {d}_{jk} {\tilde{d}}_{jk} , j = 1 , … , {j}_{0} - 1$$
and the satisfaction of the relation:
Σⱼ₌₁^{J} Fⱼ²≦ε²,
wherein (dⱼₖ) and (\tilde{d}_{j′k′}) are orthogonal sequences, (\tilde{d}ⱼₖ)_{k ε Δ}_{ⱼ} are wavelet coefficients of the disturbance signal at the coarsest approximation level j₀ over the disturbance interval I_{d}, where Δⱼ={k: supp ψⱼₖ⊂I_{d}}, k corresponds to the wavelet coefficients at a level, supp ψⱼₖ corresponds to a mother wavelet, and [symbol] are wavelet coefficients of the pure signal at the scale level j and [symbol] is a level group, and Fⱼ corresponds to a result in the interruption fault event type determination.

4. The voltage events detection and classification system according to claim 3, wherein the finest detail level is utilized to detect a start time, an end time, and a duration of a voltage event, and the coarsest level is utilized to classify a voltage event.

5. A computer software product, comprising a non-transitory medium readable by a processor, the non-transitory medium having stored thereon a set of instructions for implementing voltage events detection and classification, the set of instructions including:
(a) a first sequence of instructions which, when executed by the processor, causes said processor to compute a first result
$${‖ ( {d}_{{j}_{0} k} ) ‖}_{{Δ}_{{j}_{0}}}$$
of a finest detail level of a pure signal based on wavelet coefficients [symbol] of said pure signal, compute a second result
$${‖ ( {\tilde{d}}_{{j}_{0} k} ) ‖}_{{Δ}_{{j}_{0}}}$$
of a coarsest level of a disturbance signal based upon wavelet coefficients (\tilde{d}ⱼₖ)_{k ε Δ}_{ⱼ} of said disturbance signal, and compute a third result r relating the second result of the coarsest level to the first result of the finest detail level, by calculation of:
a first formula calculating the first result of the finest detail level of said pure signal characterized by the relation:
$${‖ ( {d}_{{j}_{0} k} ) ‖}_{{Δ}_{{j}_{0}}} = {( {\sum }_{k ∈ {Δ}_{{j}_{0}}} {d}_{{j}_{0} k}^{2} )}^{\frac{1}{2}} ;$$
a second formula calculating the second result of the coarsest level of said disturbance signal characterized by the relation:
$${‖ ( {\tilde{d}}_{{j}_{0} k} ) ‖}_{{Δ}_{{j}_{0}}} = {( {\sum }_{k ∈ {Δ}_{{j}_{0}}} {\tilde{d}}_{{j}_{0} k}^{2} )}^{\frac{1}{2}} ;$$
and
a third formula calculating the third result r relating the second result of the coarsest level to the first result of the finest detail level, characterized by the relation:
$$r = \frac{{‖ ( {\tilde{d}}_{{j}_{0} , k} ) ‖}_{{Δ}_{{j}_{0}}}}{{‖ ( {d}_{{j}_{0} k} ) ‖}_{{Δ}_{{j}_{0}}}} ;$$
(b) a second sequence of instructions which, when executed by the processor, causes said processor to determine a no fault event type based on the relation:
(1−ε)≦r≦(1+ε),
where ε is a preassigned threshold;
(c) a third sequence of instructions which, when executed by the processor, causes said processor to determine a swell fault event type based on the relation:
r>(1+ε);
(d) a fourth sequence of instructions which, when executed by the processor, causes said processor to determine a sag fault event type based on the relation:
ε≦r<(1−ε); and
(e) a fifth sequence of instructions which, when executed by the processor, causes said processor to determine, when r<ε, that an interruption fault event type has occurred based on the computation of:
$${F}_{j} = {\sum }_{k ∈ {Δ}_{j}} {d}_{jk} {\tilde{d}}_{jk} , j = 1 , … , {j}_{0} - 1$$
and the satisfaction of the relation:
Σⱼ₌₁^{j} Fⱼ²≦ε²,
wherein (dⱼₖ) and (\tilde{d}_{j′k′}) are orthogonal sequences, (\tilde{d}ⱼₖ)_{k εΔ}_{ⱼ} are wavelet coefficients of the disturbance signal at the coarsest approximation level j₀ over the disturbance interval I_{d}, where Δⱼ=[k: supp ψⱼₖ⊂I_{d}}, k corresponds to the wavelet coefficients at a level, supp ψⱼₖ corresponds to a mother wavelet, and [symbol] are wavelet coefficients of the pure signal at the scale level j and [symbol] is a level group, and Fⱼ corresponds to a result in the interruption fault event type determination.

6. The computer software product according to claim 5, wherein the finest detail level is utilized to detect a start time, an end time, and a duration of a voltage event, and the coarsest level is utilized to classify a voltage event.
